(19) United States
(12) Patent Application Publication
(10) Pub. No.: US 2015/0250049 A1
(43) Pub. Date: Sep. 3, 2015

(54) FLEXIBLE CIRCUIT BOARD WITH STRETCHABLE EXTENSION SECTION

(71) Applicant: ADVANCED FLEXIBLE CIRCUITS CO., LTD., TAOYUAN COUNTY (TW)

(72) Inventors: KUO-FU SU, TAOYUAN COUNTY (TW); GWUN-JIN LIN, TAOYUAN COUNTY (TW)

(21) Appl. No.: 14/621,945

(22) Filed: Feb. 13, 2015

(30) Foreign Application Priority Data
Mar. 3, 2014 (TW) 103106951

(51) Int. Cl. H05K 1/02; H01R 12/62; H05K 1/03

(52) U.S. Cl. CPC H05K 1/0271; H05K 1/028; H05K 1/0283; H05K 1/03; H01R 12/62; H05K 1/0313; H05K 2201/0162

(57) ABSTRACT

A flexible circuit board includes a first connection section and a second connection section between which a stretchable extension section is connected and has at least a portion that is shapeable by a shapeable material layer to form a spiral section. The spiral section is stretchable in the extension direction. The spiral section provides the flexible circuit board with characteristics of better flexibility, stretchability, capability of eliminating stresses induced in multiple directions.

### BACKGROUND OF THE INVENTION

1. Field of the Invention

The present invention relates to a flexible circuit board, and in particular to a flexible circuit board which comprises at least one stretchable extension section to provide the flexible circuit board with a structure that is stretchable in an extension direction and that eliminates stresses induced in multiple directions.

2. The Related Arts

In most of a variety of electronic devices that are used contemporarily, due to the amount of transmission through signal lines getting increasingly large, the number of signal lines involved is also getting larger and larger. In the technology of looping signal transmission lines, techniques related to flexible circuit boards are most promising ones. A flexible circuit board features light weights and small volumes and is generally used for meeting the conditions of assembling system products having various outside appearances so as to increase wiring density to serve as a circuit carrier for signal connection or component assembling. The flexible circuit board can be used to connect active, passive, and modular components and thus, the flexible circuit boards also show characteristics in respect of mechanism.

The flexible circuit boards have been widely used in various system products, such as compact electronic products. For example, consumers electronic products, such as mobile phones, digital cameras, computer peripherals, flat panel displays, and game machines, commonly use the flexible circuit boards, particularly for use in hinge parts of the electronic products, including clamshell, slip, and flip types of rotary device bodies. However, the conventional flexible circuit board is not stretchable and bendable so that although the flexible circuit board is flexible, but the flexibility is limited. Excessive bending often results in breaking or damage of metal material involved in the flexible circuit board.

Further, a hinge structure that is commonly used in electronic devices requires extension of a flexible circuit board through a narrow hole or bore (such as that found in a slip cover mobile phone). To allow a flexible circuit board to extend through a hinge structure of an electronic device, the flexible circuit board must be made stretchable to certain extent and is subjected to constrain in the direction of translation in the passage thereof through the bore so as not to eliminate stresses induced in multiple directions. Thus, it is an issue of development to be handled by those involved in the industry to overcome the technical insufficiencies discussed above.

### SUMMARY OF THE INVENTION

Thus, to overcome the above problems, an object of the present invention is to provide a flexible circuit board structure that allows for extension of a predetermined length in order to achieve the purposes of stretching of the flexible circuit board and eliminating stresses induced in multiple directions.

To achieve the above object, the present invention provides a flexible circuit board, which comprises a stretchable extension section of which at least a portion is shapeable by a shapeable material layer to form a spiral section.

In a preferred embodiment, the stretchable extension section is made by thermoplastic materials. The thermoplastic material, after being shaped through thermo-plasticity, sets at least a portion of the stretchable extension section in a shape that forms a spiral structure.

In respect of electric properties, materials that are used to make the shapeable material layer can be selected from insulation materials, comprising silicone rubber, rubber, silicone, plastics, and resin, or electrically conductive materials comprising silicone rubber, rubber, silicone, plastics, and resin containing conductively particles therein. In a preferred embodiment, the stretchable extension section is received through a bore of a hinge structure or wrapped around an outer circumferential surface of an axle or is arranged on outside or inside of arm joint.

In a preferred embodiment, the stretchable extension section comprises a plurality of cluster lines formed by slitting in the extension direction.

In a preferred embodiment, the flexible circuit board is a single-sided flexible circuit board or alternatively a double-sided board or a multiple layered board.

In a preferred embodiment, one of the first connection section and the second connection section of the flexible circuit board of the present invention comprises a plurality of signal terminals formed thereon and also comprises a plurality of solder pad zones formed thereon. In a preferred embodiment, the flexible circuit board of the present invention comprises a plurality of conductive lines, and the conductive lines comprise at least one pair of differential mode signal lines for transmitting differential mode signals.

In the efficacy, since the stretchable extension section has at least a portion that is in the form of a spiral structure, the stretchable extension section is stretchable in an extension direction of a flexible circuit board. With the structural arrangement of the present invention, adaptability of assembling is improved and no additional space for the elongation of the flexible circuit board needs to be preserved. With the shapeable material layer enclosing and coupled to the stretchable extension section, a water resistant effect can be obtained when the flexible circuit board is combined to an enclosure of an electronic device. With the spiral section of the present invention, the flexible circuit board provides effects of improved flexibility, stretchability, and capability of eliminating stresses induced in multiple directions.

The present invention is applicable to an embodiment comprising cluster lines. Since the flexible circuit board allows for reduction of a transverse width, passing through a narrow hole or a bore is facilitated and spatial arrangement of electronic components and wiring is also improved.

The flexible circuit board of the present invention comprises a stretchable extension section that comprises a spiral section that is wrapable around an outer circumferential surface of an axle of an electronic device or arranged along outside or inside of a structure of an arm joint so as to widen the application of the flexible circuit board.

### BRIEF DESCRIPTION OF THE DRAWINGS

The present invention will be apparent to those skilled in the art by reading the following description of preferred embodiments of the present invention, with reference to the attached drawings, in which:

FIG. 1 is a schematic view showing a flexible circuit board according to a first embodiment of the present invention;

FIG. 2 is a cross-sectional view taken along line 2-2 of FIG. 1;

FIG. 3 is a cross-sectional view taken along line 3-3 of FIG. 1;

FIG. 4 is a schematic view showing a first connection section and a second connection section of a stretchable and flexible circuit board according to the present invention receiving an electronic component inserted therein and coupled thereto;

FIG. 5 is a schematic view showing a flexible circuit board according to a second embodiment of the present invention;

FIG. 6 is a cross-sectional view taken along line 6-6 of FIG. 5;

FIG. 7 is a cross-sectional view showing a cross section of cluster lines of a stretchable extension section converged in the form of a circle;

FIG. 8 is a schematic view showing a flexible circuit board according to the present invention received through a hinge structure of an electronic device;

FIG. 9 is a schematic view showing a flexible circuit board according to the present invention wrapped around an axle structure of an electronic device;

FIG. 10 is another schematic view showing a flexible circuit board according to the present invention wrapped around an axle structure of an electronic device;

FIG. 11 is another schematic view showing a flexible circuit board according to the present invention wrapped around an axle structure of an electronic device;

FIG. 12 is a schematic view showing a flexible circuit board according to the present invention combined outside a movable arm joint structure;

FIG. 13 is a cross-sectional view showing an embodiment of the present invention in a double-sided flexible circuit board; and

FIG. 14 is another cross-sectional view showing an embodiment of the present invention in a double-sided flexible circuit boar in a sectioned form, showing the second embodiment of the present invention.

### DETAILED DESCRIPTION OF THE PREFERRED EMBODIMENTS

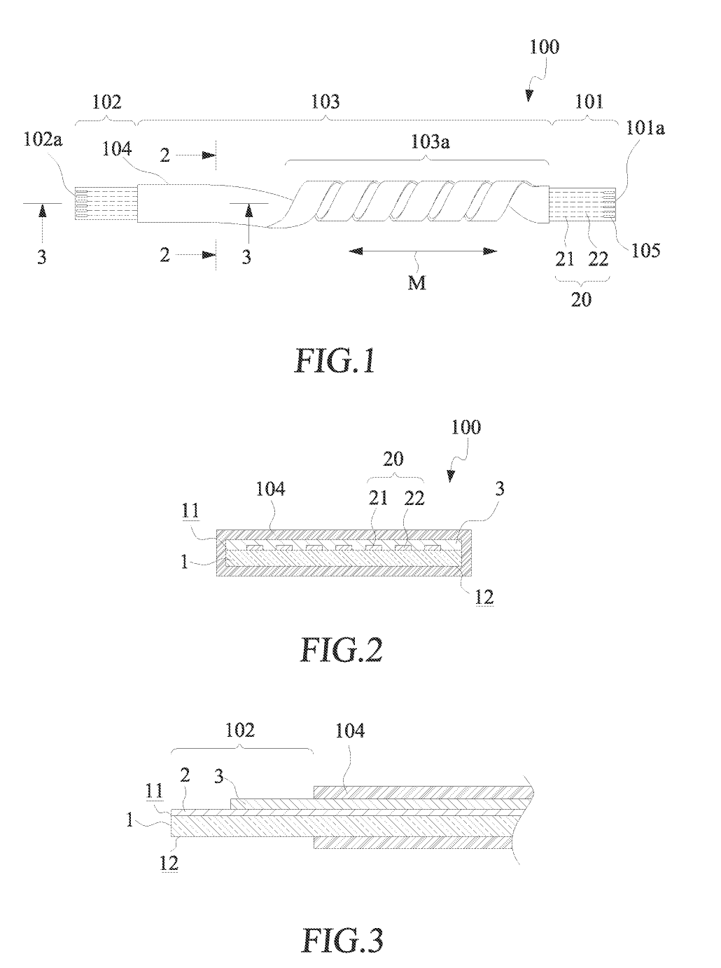

With reference to the drawings and in particular to FIG. 1, a schematic view is given to show a flexible circuit board according to a first embodiment of the present invention. As shown in the drawing, the flexible circuit board 100 comprises a first connection section 101, which is in the form of a flat plate, and a first end section 101a formed at an end of the first connection section 101. A second connection section 102, which is in the form of a flat plate, is provided, at an end thereof, with a second end section 102a. Connected between the first connection section 101 and the second connection section 102 is a stretchable extension section 103 that is in the form of a flat plate and extends in an extension direction M.

The flexible circuit board 100 comprises a plurality of conductive lines 20 formed thereon to extend substantially parallel to each other. The conductive lines 20 comprise at least one pair of differential mode signal lines 21, 22 for transmission of a differential mode signal. The differential mode signal lines 21, 22 are arranged symmetric and in combination with an adjacently located grounding line.

The stretchable extension section 103 has an outside surface, which is provided thereon with a shapeable material layer 104 to be enclosed thereby. The shapeable material layer 104 is selected from thermoplastic materials so that at least a portion of the stretchable extension section 103 is shapeable by the shapeable material layer 104 to form a spiral section 103a, whereby the spiral section 103a is stretchable by a length in the extension direction M. Referring to FIG. 2, a cross-sectional taken along line 2-2 is shown. FIG. 3 is a cross-sectional view taken along line 3-3 of FIG. 1. As shown in the drawings, the flexible circuit board 100 according to the present invention can be of a structure of a single-sided flexible circuit board, which comprises a flexible substrate 1. The flexible substrate 1 has a first substrate surface 11 and a second substrate surface 12, wherein the first substrate surface 11 of the flexible substrate 1 comprises a first metal layer 2 formed thereon. The conductive lines 20 are formed of the first metal layer 2. The first metal layer 2 comprises a first insulation layer 3 formed thereon.

In respect of electric properties, materials that are used to make the shapeable material layer 104 can be of two options, one being an insulation material, selected from one of silicone rubber, rubber, silicone, plastics, and resin, while another option being an electrically conductive material selected from one of silicone rubber, rubber, silicone, plastics, and resin containing conductively particles therein.

In the first embodiment illustrated in FIG. 1, the first end section 101a of the first connection section 101 and the second end section 102a of the second connection section 102 are respectively provided with a plurality of signal terminals 105.

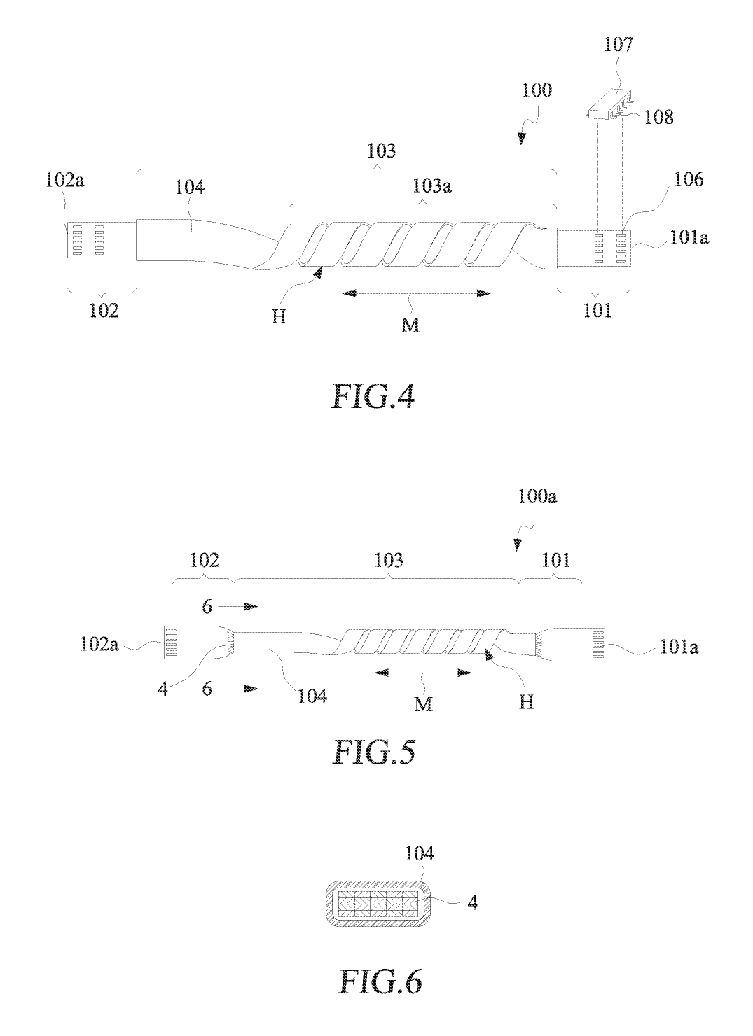

Referring to FIG. 4, a schematic view is given to show the first connection section 101 and a second connection section 102 of the flexible circuit board according to the present invention receive an electronic component inserted therein and coupled thereto. As shown in the drawing, the first connection section 101 and the second connection section 102 of the flexible circuit board 100 are provided with a plurality of solder pad zones 106. The solder pad zones 106 may receive an electronic component 107 set at a location corresponding thereto for being coupled thereto. Signal pins 108 of the electronic component 107 can be mounted through regular soldering to the solder pad zone 106. The electronic component 107 can be a surface-mount device (SMD), such as a connector and an insertion socket.

Referring to FIG. 5, a schematic view is given to show a flexible circuit board according to a second embodiment of the present invention. FIG. 6 is a cross-sectional view taken along line 6-6 of FIG. 5. As shown in the drawings, in the instant embodiment, most of the components/parts are similar to those of the first embodiment and identical components/parts are designated with the same reference numerals for consistency.

The flexible circuit board 100a of the second embodiment of the present invention similarly comprises a first connection section 101, a second connection section 102, a stretchable extension section 103, and a shapeable material layer 104.

The stretchable extension section 103 of the flexible circuit board 100a is connected between the first connection section 101 and the second connection section 102. The stretchable extension section 103 comprises a plurality of cluster lines 4 that is formed by slitting made in the extension direction M so that the cluster lines 4 are separate from each other and are movable independent of each other.

The stretchable extension section 103 is enclosed by and coupled to a shapeable material layer 104. The shapeable material layer 104 is selected from the thermoplastic materials, so that after being shaped through thermo-plasticity of the thermoplastic material, the cluster lines 4 of the stretchable extension section 103 are converged together and shaped to form a spiral section 103a, whereby the stretchable extension section 103 is stretchable in the extension direction M.

Similarly, in respect of electric properties, materials that are used to make the shapeable material layer 104 can be of two options, one being an insulation material, selected from one of silicone rubber, rubber, silicone, plastics, and resin, while another option being an electrically conductive material selected from one of silicone rubber, rubber, silicone, plastics, and resin containing conductively particles therein.

Since the stretchable extension section 103 is formed of a plurality of cluster lines 4 that is formed through slitting made in the extension direction, a transverse width of the stretchable extension section 103 is greatly reduced to allow for easy passage through a narrow hole or bore and also facilitate spatial arrangement of electronic components and wiring.

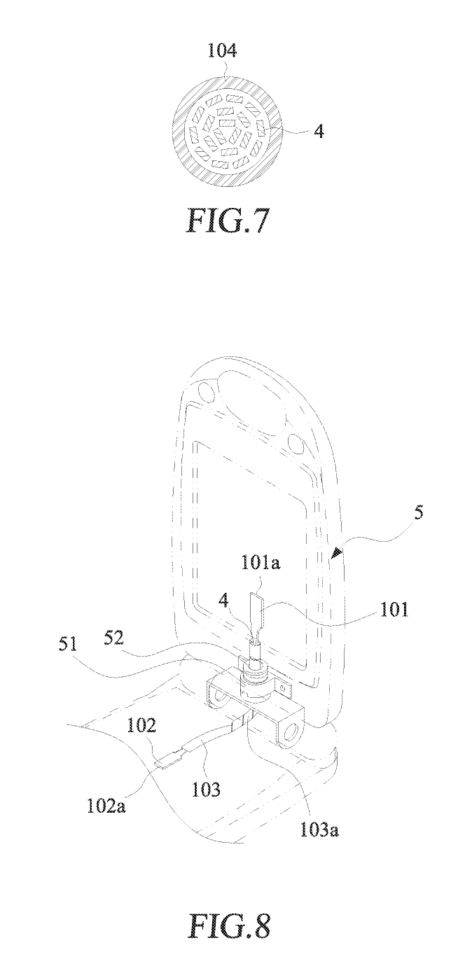

In FIG. 6, when the shapeable material layer 104 is set to enclose and couple to the stretchable extension section 103, the cluster lines 4 of the stretchable extension section 103 are converged together to form a flat cross section. FIG. 7 illustrates that the shapeable material layer 104 of FIG. 6 that enclose outside the stretchable extension section 103 can be made in such a way that the cluster lines 4 of the stretchable extension section 103 are converged to show a circular cross section.

The flexible circuit board according to the present invention is combinable with structures of electronic devices. Referring to FIG. 8, a schematic view is given to show a flexible circuit board according to the present invention received through a hinge structure of an electronic device. The stretchable extension section 103 of the flexible circuit board 100 is insertable through a narrow hole or a bore 52 of a hinge structure 51 of an electronic device 5 so that the first connection section 101 and the second connection section 102 are respectively set at opposite ends of the bore 52. Due to the stretchable extension section 103 comprising the spiral section 103a, stretching can be made in the extension direction M and an advantage of eliminating stresses induced in multiple directions can be achieved.

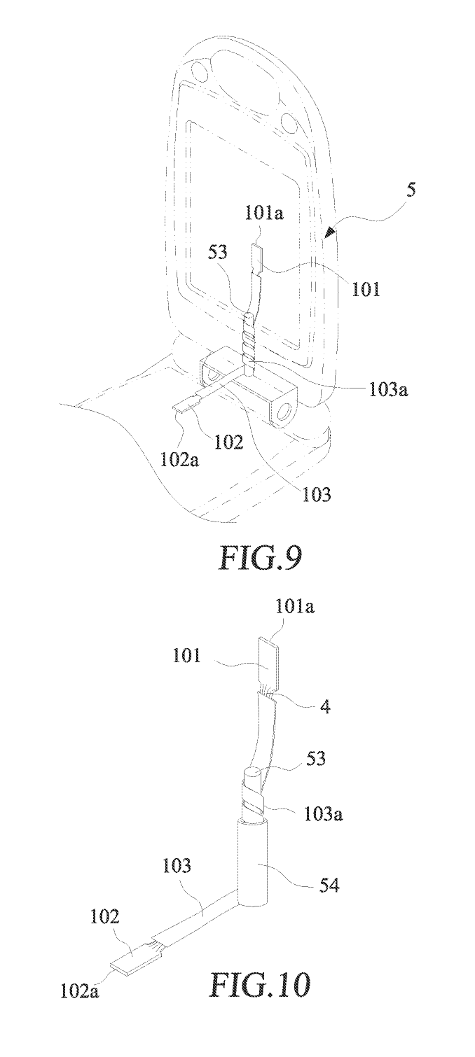

Referring to FIG. 9, a schematic view is given to show a flexible circuit board according to the present invention wrapped around an axle structure of an electronic device. As shown in the drawing, the spiral section 103a of the flexible circuit board 100 can be wrapped around an outer circumferential surface of an axle 53 of the electronic device 5.

Referring to FIG. 10, another schematic view is given to show a flexible circuit board according to the present invention wrapped around an axle structure of an electronic device. The axle 53 shown in FIG. 9 is further provided, around the outer circumferential surface thereof, with an external axle cover 54 to improve product aesthetics.

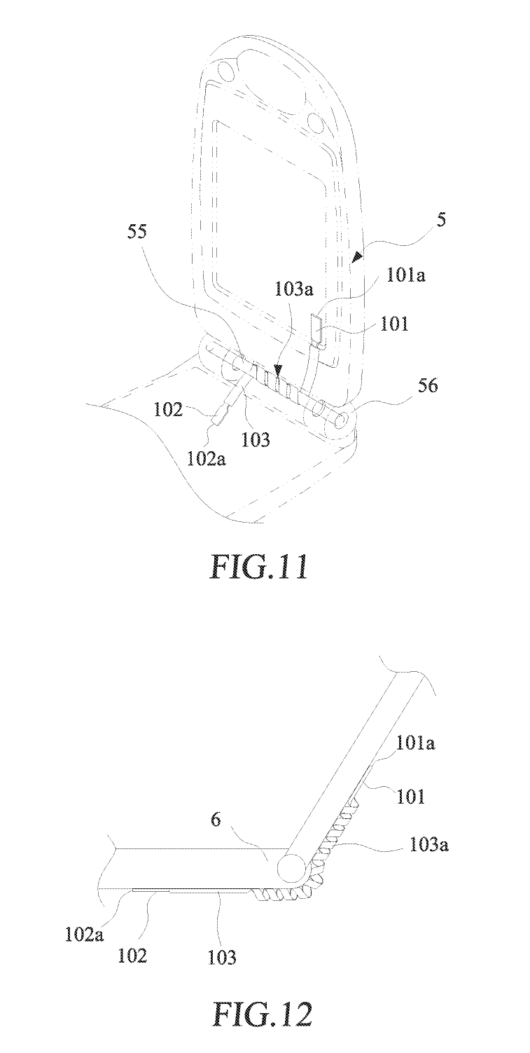

Referring to FIG. 11, another schematic view is given to show a flexible circuit board according to the present invention wrapped around an axle structure of an electronic device. As shown in the drawing, in an application to opening/closing of an electronic device 5 (such as a notebook computer or a flip type mobile phone), the electronic device 5 comprises an axle 55 and the axle 55 serves as a central axis for opening/closing of the electronic device 5 and comprises positioning sections 56 at opposite ends for positioning and coupling the axle 55. The spiral section 103a of the stretchable extension section 103 is arranged to wrap around an outer circumferential surface of the axle 55.

Referring to FIG. 12, a schematic view is given to show a flexible circuit board according to the present invention combined outside a movable arm joint structure. As shown in the drawing, the present invention can be used outside an electronic device 5 (such as a robotic arm). In this application, the spiral section 103a of the stretchable extension section 103 of the flexible circuit board 100 is arranged to extend along an outside or inside of a structure of an arm joint 6.

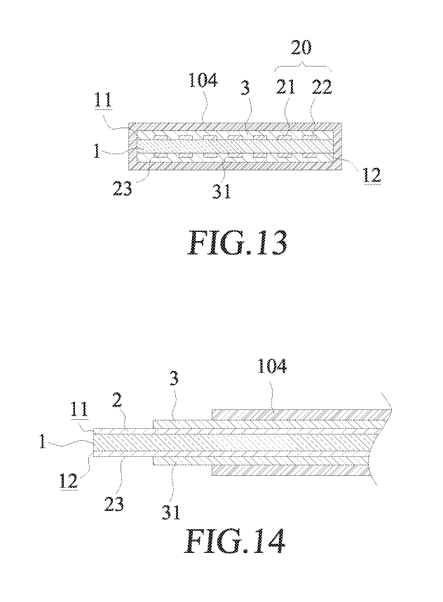

The previous embodiments are described on the basis of single-sided flexible circuit boards; however, application can also be made to double-sided or multiple-layered circuit boards. For example, FIG. 13 provides a cross-sectional view showing an embodiment of the present invention in a double-sided flexible circuit board and FIG. 14 another cross-sectional view showing an embodiment of the present invention in a double-sided flexible circuit boar in a sectioned form, showing the second embodiment of the present invention. As shown in the drawings, the double-sided flexible circuit board comprises a flexible substrate 1. The flexible substrate 1 has a first substrate surface 11 and a second substrate surface 12. The flexible substrate 1 comprises a first metal layer 2 formed on the first substrate surface 11 and a first insulation layer 3 formed on the first metal layer 2. The flexible substrate 1 comprises a second metal layer 23 formed on the second substrate surface 12 and a second insulation layer 31 formed on the second metal layer 23. The second metal layer 23 can be a grounding layer.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A flexible circuit board, comprising:
a first connection section;
a second connection section;
a stretchable extension section connected between the first connection section and the second connection section, the stretchable extension section extending in an extension direction; and
a shapeable material layer coupling to the stretchable extension section:
wherein the stretchable extension section has at least a portion that is shapeable by the shapeable material layer to form a spiral section, and the spiral section is stretchable in the extension direction.

2. The flexible circuit board as claimed in claim 1, wherein the shapeable material layer is made by thermoplastic materials.

3. The flexible circuit board as claimed in claim 1, wherein the shapeable material layer comprises a material selected from insulation materials comprising silicone rubber, rubber, silicone, plastics, and resin.

4. The flexible circuit board as claimed in claim 1, wherein the shapeable material layer comprises a material selected from electrically conductive materials comprising silicone rubber, rubber, silicone, plastics, and resin, which contain therein conductive particles.

5. The flexible circuit board as claimed in claim 1, wherein the stretchable extension section is receivable through a bore of a hinge structure.

6. The stretchable and flexible circuit board as claimed in claim 1, wherein the stretchable extension section is wrapped around an outer circumferential surface of an axle.

7. The flexible circuit board as claimed in claim 1, wherein the stretchable extension section is arranged along outside or inside of an arm joint.

8. The flexible circuit board as claimed in claim 1, wherein the stretchable extension section comprises a plurality of cluster lines formed by slitting in the extension direction.

9. The flexible circuit board as claimed in claim 1, comprising:
a flexible substrate, which has a first substrate surface and a second substrate surface;
a first metal layer, which is formed on the first substrate surface of the flexible substrate; and
a first insulation layer, which is formed on the first metal layer.

10. The flexible circuit board as claimed in claim 9, wherein the flexible circuit board further comprises:
a second metal layer, which is formed on the second substrate surface of the flexible substrate; and
a second insulation layer, which is formed on a surface of the second metal layer.

11. The flexible circuit board as claimed in claim 1, wherein one of the first connection section and the second connection section comprises a plurality of signal terminals formed thereon.

12. The flexible circuit board as claimed in claim 1, wherein one of the first connection section and the second connection section comprises a plurality of solder pad zones formed thereon.

13. The flexible circuit board as claimed in claim 1, further comprising a plurality of conductive lines formed on the flexible circuit board, and the conductive lines comprising at least one pair of differential mode signal lines for transmitting differential mode signals.
